(19) United States
(12) Patent Application Publication
(10) Pub. No.: US 2012/0299144 A1
(43) Pub. Date: Nov. 29, 2012

(54) SEMICONDUCTOR LIGHT RECEIVING DEVICE

(75) Inventors: Masaharu NAKAJI, Tokyo (JP); Ryota TAKEMURA, Tokyo (JP)

(73) Assignee: MITSHUBISHI ELECTRIC CORPORATION, Tokyo (JP)

(21) Appl. No.: 13/340,077

(22) Filed: Dec. 29, 2011

(30) Foreign Application Priority Data
May 23, 2011 (JP) 2011-114964

(51) Int. Cl. H01L 27/144

(52) U.S. Cl. 257/443; 257/E27.127

(57) ABSTRACT

A semiconductor light-detecting device includes: a semi-insulating substrate; and n light-detecting elements (n is a natural number equal to or larger than 4) electrically isolated from each other and on the semi-insulating substrate. Each light-detecting element includes a conductive layer of a first conductivity type, a light absorption layer, a window layer, and an impurity diffusion region of a second conductivity type, which are laminated, one on another, on the semi-insulating substrate. The light absorption layer is a photoelectrical converter. The impurity diffusion region is located in part of the window layer and serves as a light-detecting section. A part of the conductive layer and the light absorption layer use the same material. The n light-detecting elements are not all located on a common straight line.

### BACKGROUND OF THE INVENTION

1. Field of the Invention

The present invention relates to a semiconductor light receiving device wherein a plurality of light-receiving elements are integrated on a semi-insulating substrate.

2. Background Art

Conventionally, one light-receiving element is enough for one semiconductor light receiving device to realize a necessary transmission capacity. However, as FTTH (Fiber To The Home) or the like becomes widespread, there is a growing demand for faster transmission of a larger volume of information. Moreover, miniaturization of packages or the like is also required. Thus, there is a trend that a plurality of light-receiving elements are integrated on one semiconductor light receiving device so that a plurality of signals are transmitted using the same number of optical fibers at a time and received by the respective light-receiving elements using lenses or the like.

However, since a plurality of signals are simultaneously transmitted at a time, the plurality of light-receiving elements need to be electrically isolated from each other. Therefore, there is a report on a semiconductor light receiving device in which a plurality of light-receiving elements are integrated on a Fe—InP semi-insulating substrate and the light-receiving elements are electrically isolated from each other (e.g., see takemura et al. ECOC2010, P2.11, 25 Gbps×4ch Photodiode Array with High Responsivity).

### SUMMARY OF THE INVENTION

In a conventional semiconductor light receiving device, light receiving sections of a plurality of light-receiving elements are spaced uniformly on the same straight line. For this reason, when a receiver that condenses light at each light receiving section using a non-spherical lens whose focus position is located at the center of the optical axis or one spherical lens is designed, influences of aberration on light receiving sections at both ends located away from the center of the optical axis increase, coupling efficiency deteriorates and light receiving sensitivity deteriorates. To reduce the influences of aberration, a large lens may be used or a lens whose focus is located on the axis of each light receiving section may be used, but such lenses become very expensive. On the other hand, narrowing spacings between the light receiving sections too much may deteriorate electrical and optical isolation, leading to a problem of electrical and optical crosstalk.

In view of the above-described problems, an object of the present invention is to provide a semiconductor light receiving device which can suppress electrical and optical crosstalk and obtain higher light receiving sensitivity even using a relatively inexpensive lens.

According to the present invention, a semiconductor light receiving device comprises: a semi-insulating substrate; and n light-receiving elements (n is a natural number equal to or greater than 4) electrically isolated from each other and on the semi-insulating substrate, wherein each light-receiving element includes a conductive layer of a first conductivity type, a light absorption layer, a window layer and an impurity diffusion region of a second conductivity type which are laminated one on another on the semi-insulating substrate, the light absorption layer is a photoelectrical converter, the impurity diffusion region is provided in part of the window layer and serves as a light receiving section, a part of the conductive layer is made of same material as the light absorption layer, and all of the n light-receiving elements are not arranged on a same straight line.

The present invention makes it possible to suppress electrical and optical crosstalk and obtain higher light receiving sensitivity even using a relatively inexpensive lens.

Other and further objects, features and advantages of the invention will appear more fully from the following description.

### BRIEF DESCRIPTION OF THE DRAWINGS

FIG. 1 is a top view illustrating a semiconductor light receiving device according to a first embodiment of the present invention.

FIG. 2 is a cross-sectional view along a line I-II in FIG. 1.

FIG. 3 is a top view illustrating a semiconductor light receiving device according to a comparative example.

FIG. 4 is a top view illustrating a semiconductor light receiving device according to a second embodiment of the present invention.

FIG. 5 is a top view illustrating a semiconductor light receiving device according to a third embodiment of the present invention.

FIG. 6 is a top view illustrating a semiconductor light receiving device according to a fourth embodiment of the present invention.

FIG. 7 is a top view illustrating a semiconductor light receiving device according to a fifth embodiment of the present invention.

FIG. 8 is a top view illustrating a semiconductor light receiving device according to a sixth embodiment of the present invention.

FIG. 9 is a top view illustrating a semiconductor light receiving device according to a seventh embodiment of the present invention.

FIG. 10 is a top view illustrating a semiconductor light receiving device according to an eighth embodiment of the present invention.

### DETAILED DESCRIPTION OF THE PREFERRED EMBODIMENTS

A semiconductor light receiving device according to the embodiments of the present invention will be described with reference to the drawings. The same components will be denoted by the same symbols, and the repeated description thereof may be omitted.

### First Embodiment

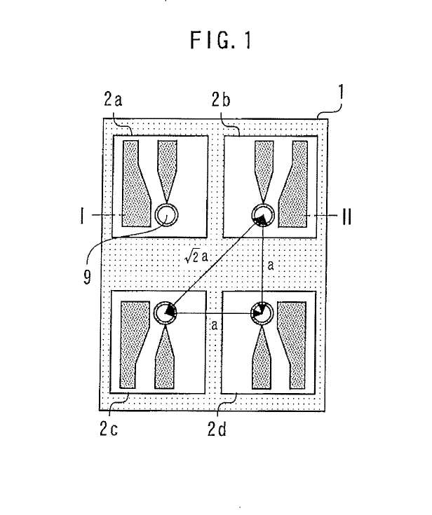

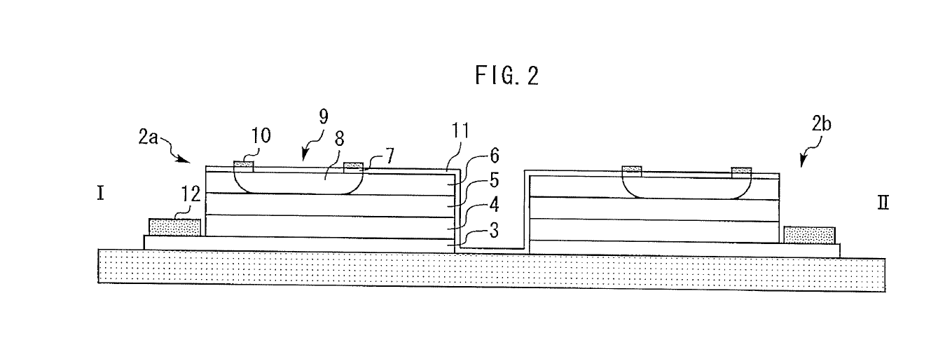

FIG. 1 is a top view illustrating a semiconductor light receiving device according to a first embodiment of the present invention. FIG. 2 is a cross-sectional view along a line I-II in FIG. 1. Four light-receiving elements 2a to 2d electrically isolated from each other are provided on an Fe—InP semi-insulating substrate 1.

In each light-receiving element 2a to 2d, an n-type InGaAs conductive layer 3 (impurity concentration 1×10¹⁹/cm³), an n-type InP conductive layer 4 (impurity concentration 1×10¹⁸/cm³, layer thickness 1 μm), a i-type InGaAs light absorption layer 5 (impurity concentration 1×10¹⁵/cm³, layer thickness 2 μm) which is a photoelectrical converter, an i-type InP window layer 6 (impurity concentration 1×10¹⁵/cm³, layer thickness 1 μm) and a p-type InGaAs contact layer 7 (layer thickness 0.5 μm) are laminated one on another on the Fe—InP semi-insulating substrate 1. A p-type InP impurity diffusion region 8 is provided in part of the i-type InP window layer 6. This p-type InP impurity diffusion region 8 serves as a light receiving section 9 of the light-receiving elements 2a to 2d.

A p-electrode 10 is connected to the p-type InGaAs contact layer 7. The surface of the light-receiving elements 2a to 2d is covered with a SiN passivation film 11. An n-electrode 12 is connected to an exposed surface of the n-type InGaAs conductive layer 3. The light receiving sections 9 of the four light-receiving elements 2a to 2d are arranged at vertices of a square.

Next, manufacturing steps of the semiconductor light receiving device according to the present embodiment will be described. First, the n-type InGaAs conductive layer 3, the n-type InP conductive layer 4, the i-type InGaAs light absorption layer 5, the i-type InP window layer 6 and an i-type InGaAs layer (not shown) (impurity concentration 1×10¹⁵/cm³) are deposited one on another on the Fe—InP semi-insulating substrate 1, using, for example, crystal growth such as a metal organic chemical vapor deposition method (MOCVD) and molecule beam epitaxy (MBE).

Next, a silicon oxide film (not shown) is deposited and four circular removed patterns having a diameter on the order of 30 μm are formed on a silicon oxide film using a photolithography technique. The four removed patterns are arranged at the vertices of the square.

Next, using this silicon oxide film as a mask, Zn is diffused using a thermal diffusion method, and the p-type InP impurity diffusion region 8 and the p-type InGaAs contact layer 7 are formed. After that, the silicon oxide film mask is removed and parts of the i-type InGaAs contact layer and the p-type InGaAs contact layer 7 are removed.

Next, using a photolithography technique, wet etching technique or dry etching technique, part of the epitaxy layer is etched in a cross shape to electrically isolate the four light-receiving elements 2a to 2d from each other. The etching depth is approximately 5 μm and etching is continued until the Fe—InP semi-insulating substrate 1 is exposed.

Next, the SiN passivation film 11 and p-electrode 10 are formed on the element surface. Furthermore, etching is performed so that the n-type InGaAs conductive layer 3 or n-type InP conductive layer 4 is exposed and the n-electrode 12 is formed on the exposed surface. Finally, the back surface of the Fe—InP semi-insulating substrate 1 is polished and divided into portions in a desired chip size through dicing. The semiconductor light receiving device according to the present embodiment is manufactured in the above-described steps.

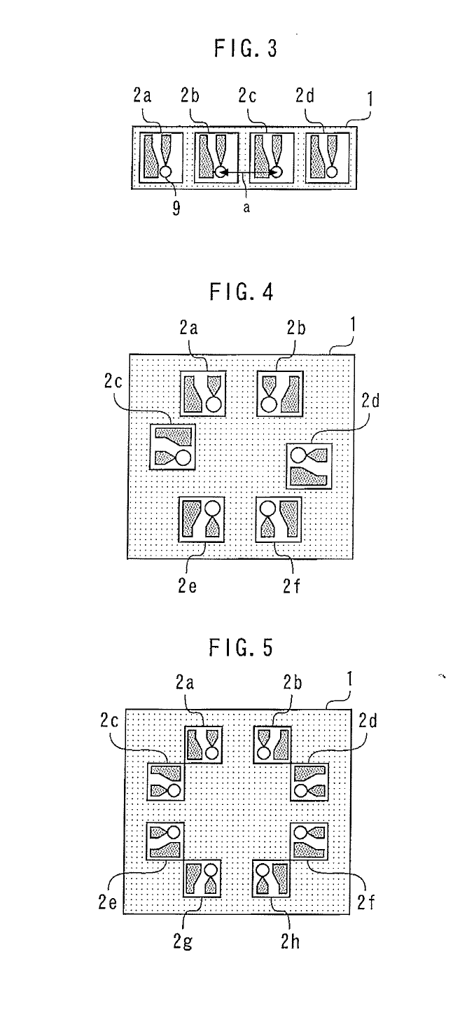

Next, effects of the present embodiment will be described in comparison with a comparative example. FIG. 3 is a top view illustrating a semiconductor light receiving device according to a comparative example. In the comparative example, light receiving sections 9 of four light-receiving elements 2a to 2d are spaced uniformly on the same straight line. Assuming the distance between the neighboring light receiving sections 9 is a, the maximum distance between the light receiving sections 9 at both ends is 3a.

On the other hand, in the present embodiment, light receiving sections 9 of four light-receiving elements 2a to 2d are arranged at vertices of a square. Thus, the maximum distance between the light receiving section 9 of the light-receiving element 2b and the light receiving section 9 of the light-receiving element 2c located on a diagonal is √2a. Therefore, in the present embodiment, the maximum distance between the light receiving sections 9 can be set to be equal to or less than half that in the comparative example.

When signals from a plurality of optical fibers are simultaneously received, light is condensed to the four light-receiving elements 2a to 2d using a lens. In this case, the distance between the light receiving sections 9 of the light-receiving elements 2a to 2d most distant from the central axis of the lens can be reduced in the present embodiment. Therefore, it is possible to easily increase coupling efficiency and obtain higher light receiving sensitivity even using a relatively inexpensive lens, which is generally used in optical communication.

Furthermore, the present embodiment provides the n-type InGaAs conductive layer 3 made of the same material as the i-type InGaAs light absorption layer 5 as part of the conductive layer present between the Fe—InP semi-insulating substrate 1 and the i-type InGaAs light absorption layer 5. This makes it possible to prevent light passing through the i-type InGaAs light absorption layer 5 from being reflected on the back surface of the Fe—InP semi-insulating substrate 1 and becoming returning light. As a result, it is possible to suppress electrical and optical crosstalk between the respective light-receiving elements.

In the present embodiment, the light receiving sections 9 of the four light-receiving elements 2a to 2d are arranged at vertices of the square, but the present invention is not limited to this and any arrangement is possible unless all the light receiving sections 9 of the light-receiving elements 2a to 2n (n is a natural number equal to or greater than 4) are arranged on the same straight line. For example, the light receiving sections 9 of the light-receiving elements 2a to 2n may be arranged at vertices of an n-sided polygon. This makes it possible to reduce the maximum distance between the light receiving sections 9 compared to the case where light receiving sections 9 of all light-receiving elements 2a to 2n are arranged on the same straight line.

Furthermore, arranging the light receiving sections 9 of n light-receiving elements 2a to 2n at vertices of the regular n-sided polygon can make uniform the distances between the respective light receiving sections 9 and the center of the optical axis. This makes it possible to equalize coupling efficiency of all light receiving sections 9 and thereby improve uniformity of characteristics.

### Second Embodiment

FIG. 4 is a top view illustrating a semiconductor light receiving device according to a second embodiment of the present invention. Light receiving sections 9 of six light-receiving elements 2a to 2f are arranged at vertices of a regular hexagon. This makes it possible to reduce the maximum distance between the light receiving sections 9 to √3a, and thereby obtain high light receiving sensitivity.

### Third Embodiment

FIG. 5 is a top view illustrating a semiconductor light receiving device according to a third embodiment of the present invention. Light receiving sections 9 of eight light-receiving elements 2a to 2h are arranged at vertices of a regular octagon. This makes it possible to reduce the maximum distance between the light receiving sections 9 to √3a, and thereby obtain high light receiving sensitivity.

### Fourth Embodiment

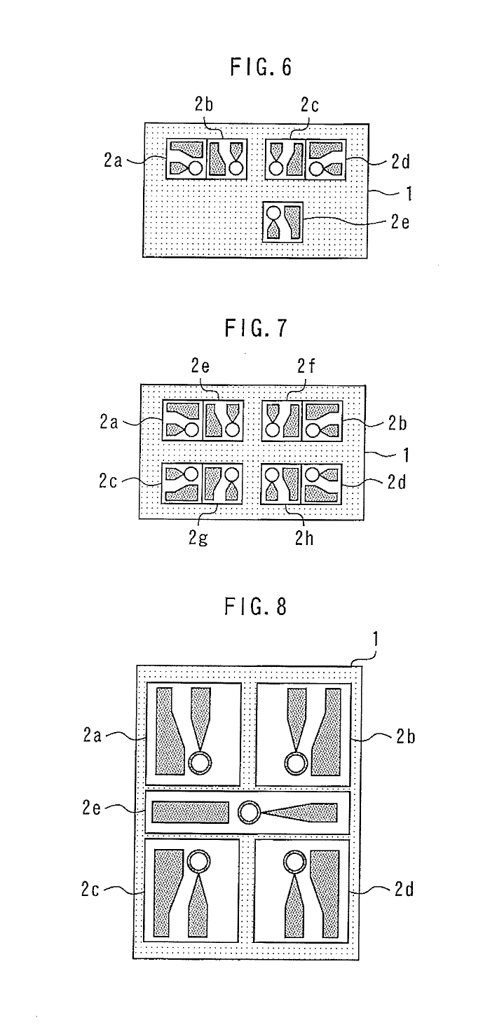

FIG. 6 is a top view illustrating a semiconductor light receiving device according to a fourth embodiment of the present invention. Of light receiving sections 9 of five light-receiving elements 2a to 2e, the light receiving section 9 of one light-receiving element 2e is not arranged on the same straight line. This makes it possible to reduce the maximum distance between the light receiving sections 9 compared to a case where the light receiving sections 9 of all the light-receiving elements 2a to 2e are arranged on the same straight line, and thereby obtain high light receiving sensitivity.

### Fifth Embodiment

FIG. 7 is a top view illustrating a semiconductor light receiving device according to a fifth embodiment of the present invention. Light receiving sections 9 of four light-receiving elements 2a to 2d out of eight light-receiving elements 2a to 2h are arranged at vertices of a rectangle and light receiving sections 9 of the remaining four light-receiving elements 2e to 2h are arranged on sides of the rectangle. This makes it possible to reduce the maximum distance between the light receiving sections 9, and thereby obtain high light receiving sensitivity.

Without being limited to this, similar effects can be obtained if light receiving sections 9 of m light-receiving elements 2a to 2m out of n light-receiving elements 2a to 2n (m is a natural number smaller than n) are arranged at vertices of an m-sided polygon and light receiving sections 9 of the remaining (n−m) light-receiving elements are arranged on sides of the m-sided polygon.

### Sixth Embodiment

FIG. 8 is a top view illustrating a semiconductor light receiving device according to a sixth embodiment of the present invention. Light receiving sections 9 of four light-receiving elements 2a to 2d out of five light-receiving elements 2a to 2e are arranged at vertices of a square and a light receiving section 9 of the remaining one light-receiving element 2e is arranged inside the square. This makes it possible to reduce the maximum distance between the light receiving sections 9, and thereby obtain high light receiving sensitivity.

Without being limited to this, similar effects can be obtained if light receiving sections 9 of m light-receiving elements 2a to 2m out of n light-receiving elements 2a to 2n (m is a natural number smaller than n) are arranged at vertices of an m-sided polygon and light receiving sections 9 of the remaining (n−m) light-receiving elements are arranged inside the m-sided polygon.

### Seventh Embodiment

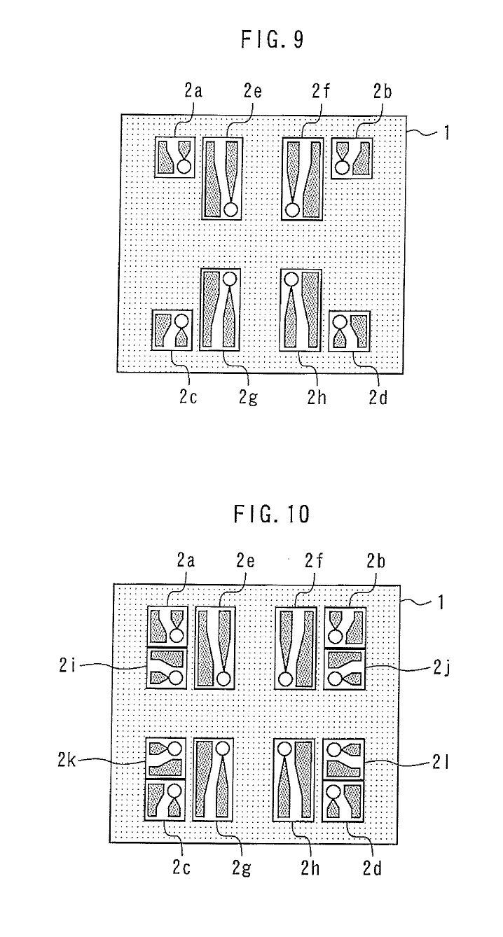

FIG. 9 is a top view illustrating a semiconductor light receiving device according to a seventh embodiment of the present invention. Light receiving sections 9 of four light-receiving elements 2a to 2d out of eight light-receiving elements 2a to 2h are arranged at vertices of a square and light receiving sections 9 of the remaining four light-receiving elements 2e to 2h are arranged at vertices of a rectangle arranged inside the square. This makes it possible to reduce the maximum distance between the light receiving sections 9, and thereby obtain high light receiving sensitivity.

Without being limited to this, similar effects can be obtained if light receiving sections 9 of m light-receiving elements 2a to 2m out of n light-receiving elements 2a to 2n (m is a natural number smaller than n) are arranged at vertices of an m-sided polygon and light receiving sections 9 of the remaining (n−m) light-receiving elements are arranged at vertices of an (n−m)-sided polygon arranged inside the m-sided polygon.

### Eighth Embodiment

FIG. 10 is a top view illustrating a semiconductor light receiving device according to an eighth embodiment of the present invention. Light receiving sections 9 of four light-receiving elements 2a to 2d out of 12 light-receiving elements 2a to 2l are arranged at vertices of a square and light receiving sections 9 of the remaining four light-receiving elements 2e to 2h are arranged at vertices of a rectangle arranged inside the square and the further remaining four light-receiving elements 2i to 2l are arranged on sides of the square. This makes it possible to reduce the maximum distance between the light receiving sections 9, and thereby obtain high light receiving sensitivity.

Without being limited to this, similar effects can be obtained if light receiving sections 9 of m light-receiving elements 2a to 2m out of n light-receiving elements 2a to 2n (m is a natural number smaller than n) are arranged at vertices of an m-sided polygon, light receiving sections 9 of k light-receiving elements of the remaining (n−m) light-receiving elements are arranged at vertices of a k-sided polygon (k is a natural number smaller than n−m) arranged inside the m-sided polygon and light receiving sections 9 of the remaining (n−m−k) light-receiving elements are arranged on sides of the m-sided polygon.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-114964, filed on May 23, 2011 including specification, claims, drawings and summary, on which the Convention priority of the present application is based, are incorporated herein by reference in its entirety.

1. A semiconductor light detecting device comprising:
a semi-insulating substrate; and
n light-detecting elements (n is a natural number equal to or larger than 4) electrically isolated from each other and on the semi-insulating substrate, wherein
each light-detecting element includes a conductive layer of a first conductivity type, a light absorption layer, a window layer, and an impurity diffusion region of a second conductivity type, which are laminated, one on another, on the semi-insulating substrate,
the light absorption layer is a photoelectrical converter,
the impurity diffusion region is located in part of the window layer and serves as a light-detecting section,
a part of the conductive layer and the light absorption layer are the same material, and
the n light-detecting elements are not all arranged on a common straight line.

2. The semiconductor light-detecting device according to claim 1, wherein the light-detecting sections of the n light-detecting elements are located at respective vertices of an n-sided polygon.

3. The semiconductor light-detecting device according to claim 2, wherein the light-detecting sections of the n light-detecting elements are located at respective vertices of a regular n-sided polygon.

4. The semiconductor light-detecting device according to claim 1, wherein
the light-detecting sections of m light-detecting elements of the n light-detecting elements (m is a natural number smaller than n) are located at respective vertices of an m-sided polygon, and
the light-detecting sections of (n−m) of the n light-detecting elements are located on sides of the m-sided polygon or inside the m-sided polygon.

5. The semiconductor light-detecting device according to claim 4, wherein the light-detecting sections of the (n−m) light-detecting elements are located at respective vertices of a (n−m)-sided polygon located inside the m-sided polygon.

6. The semiconductor light-detecting device according to claim 4, wherein the light-detecting sections of k light-detecting elements (k is a natural number smaller than n−m) of the (n−m) light-detecting elements are located at respective vertices of a k-sided polygon that is located inside the m-sided polygon, and
the light-detecting sections of (n−m−k) light-detecting elements are located on sides of the m-sided polygon.

7. The semiconductor light-detecting device according to claim 4, wherein the light-detecting sections of the m light-detecting elements are located at respective vertices of a regular m-sided polygon.
